(19) United States
(12) Patent Application Publication
(10) Pub. No.: US 2020/0153214 A1
(43) Pub. Date: May 14, 2020

(54) ELECTRONICS ENCLOSURE DEVICE

(71) Applicants: Doug Vaught, Winter Garden, FL (US); Samir Burshan, Winter Garden, FL (US); Jerry Jackson, Winter Garden, FL (US)

(72) Inventors: Doug Vaught, Winter Garden, FL (US); Samir Burshan, Winter Garden, FL (US); Jerry Jackson, Winter Garden, FL (US)

(21) Appl. No.: 16/679,708

(22) Filed: Nov. 11, 2019

Related U.S. Application Data
(60) Provisional application No. 62/758,539, filed on Nov. 10, 2018.

(51) Int. Cl. H02G 3/08; H05K 5/00; H01R 4/2433; H01R 13/74; H01R 24/76

(52) U.S. Cl. CPC H02G 3/081; H05K 5/0004; H02G 3/086; H01R 13/74; H01R 24/76; H01R 4/2433

(57) ABSTRACT

An electronics enclosure device includes a main body having a generally flat back surface and a plurality of side walls that define an interior space. A central opening is positioned through the back surface and a plurality of mounting apertures are provided to secure the main body onto a wall such that an electrical and/or communications outlet is positioned through the central opening. A plurality of user-supplied electronic components can be secured to the back surface of the main body and connected to the wall outlet. The main body includes a plurality of air vents and cable management apertures, and a cover is removably secured onto the front of the main body. One or more relocatable power taps are positioned within the main body having at least one electric outlet that is positioned through openings in the main body so as to be accessible by external components.

### CROSS-REFERENCE TO RELATED APPLICATIONS

This application claims the benefit of U.S. Application Ser. No. 62/758,539 filed on Nov. 10, 2018, the contents of which are incorporated herein by reference.

### TECHNICAL FIELD

The present invention relates generally to portable electronic enclosure devices, and more particularly to a wall mounted electronic enclosure device.

### BACKGROUND

The statements in this section merely provide background information related to the present disclosure and may not constitute prior art.

Within the hotel industry, it is common to utilize many different types of portable electronic components to provide various services to hotel guests and staff. For example, virtually every hotel room now has a computer modem, cable router, and/or electronic door or keypad systems. In some instances, an electronic component that is physically located in one room may be providing service to multiple rooms. Because these components are not intended to be touched or physically accessed by guests, they are typically located at hard to reach locations, such as beneath or within cabinets, for example. Although this helps to disguise the location of the components, they still must be physically coupled to an electrical outlet and/or communications cable to function.

Unfortunately, it is not uncommon for a hotel guest to innocently unplug one or more of these electrical components in order to access the electrical outlet for their personal devices. Additionally, there have been reported cases of unscrupulous guests who purposely find and tamper with the hotel electronic components for any number of different (and often illicit) reasons. In either instance, guest services are degraded or hampered by such activities.

Accordingly, it would be beneficial to provide a dual-purpose electronics enclosure device that can simultaneously protect electronic components from intentional or unintentional tampering by guests, while also providing accessible electrical outlets for such guests to use.

### SUMMARY OF THE INVENTION

The present invention is directed to an electronics enclosure device. One embodiment of the present invention can include a main body having a generally flat back surface and a plurality of side walls that define an interior space. A central opening can be positioned through the back surface and a plurality of mounting apertures can be provided to secure the main body onto a wall such that an electrical and/or communications outlet is positioned through the central opening.

In one embodiment, a plurality of user-supplied electronic components can be secured to the back surface of the main body and connected to the wall outlet. The main body can include a plurality of air vents and cable management apertures for connecting the user-supplied electronic components to external devices, and a cover can be secured onto the front of the main body to restrict access to the components.

In one embodiment, one or more relocatable power taps can be positioned within the main body and can be connected to the wall mounted outlet. Each of the relocatable power taps can include one or more electric outlets that can be positioned through openings in the main body so as to be accessible by components located outside of the main body.

This summary is provided merely to introduce certain concepts and not to identify key or essential features of the claimed subject matter.

### BRIEF DESCRIPTION OF THE DRAWINGS

Presently preferred embodiments are shown in the drawings. It should be appreciated, however, that the invention is not limited to the precise arrangements and instrumentalities shown.

FIG. 1 is a perspective view of the main body of the electronics enclosure device, in accordance with one embodiment of the invention.

FIG. 2 is another perspective view of the main body of the electronics enclosure device, in accordance with one embodiment of the invention.

FIG. 3 is a front view of the electronics enclosure device in operation, in accordance with one embodiment of the invention.

FIG. 4 is a perspective view of the fully assembled electronics enclosure device in operation, in accordance with one embodiment of the invention

### DETAILED DESCRIPTION OF THE INVENTION

While the specification concludes with claims defining the features of the invention that are regarded as novel, it is believed that the invention will be better understood from a consideration of the description in conjunction with the drawings. As required, detailed embodiments of the present invention are disclosed herein; however, it is to be understood that the disclosed embodiments are merely exemplary of the invention which can be embodied in various forms. Therefore, specific structural and functional details disclosed herein are not to be interpreted as limiting, but merely as a basis for the claims and as a representative basis for teaching one skilled in the art to variously employ the inventive arrangements in virtually any appropriately detailed structure. Further, the terms and phrases used herein are not intended to be limiting, but rather to provide an understandable description of the invention.

### Definitions

As described throughout this document, the term “complementary shape,” and “complementary dimension,” shall be used to describe a shape and size of a component that is identical to, or substantially identical to the shape and size of another identified component within a tolerance such as, for example, manufacturing tolerances, measurement tolerances or the like.

As described herein, the terms “connector” and “complementary connector” include any number of different elements that work independently or together to join two items together in a nonpermanent manner. Several nonlimiting examples include opposing strips of hook and loop material (i.e. Velcro®), attractively-oriented magnetic elements or magnetic and metallic elements, tethers such as zip ties, buckles such as side release buckles, and compression fittings such as T-handle rubber draw latches, hooks, snaps and buttons, for example. Each illustrated connector and complementary connector can be permanently secured to the illustrated portion of the device via a permanent sealer such as glue, adhesive tape, or stitching, for example.

As described herein, the term “removably secured” and derivatives thereof shall be used to describe a situation wherein two or more objects are joined together in a non-permanent manner so as to allow the same objects to be repeatedly joined and separated. This can be accomplished through the use of any number of connectors.

Although described throughout this document for use with the hotel industry, this is for illustrative purposes only, as the inventive concepts are not limited to any particular industry or application. Moreover, although described as a wall-mountable unit, those of skill in the art will recognize that the device may be positioned on any number of different surfaces in either a vertical or horizontal configuration. As such, the device is not limited to use as a wall-mounted component for the hotel industry.

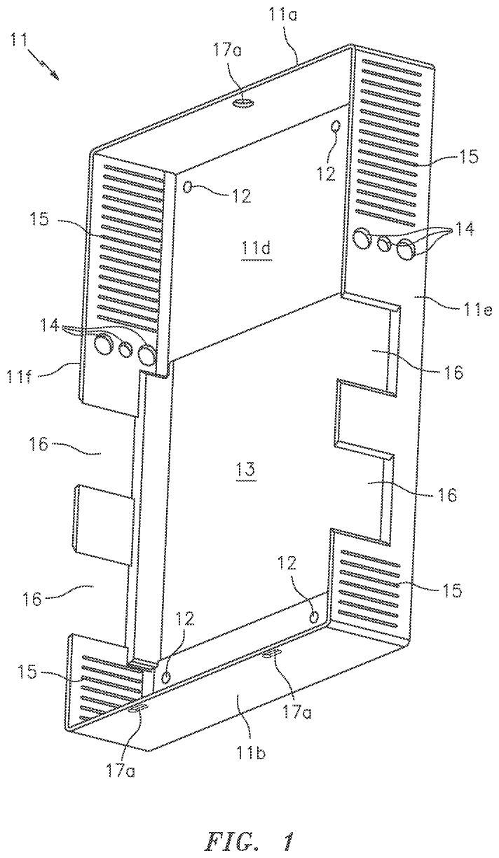

FIGS. 1-4 illustrate one embodiment of an electronics enclosure device 10 that are useful for understanding the inventive concepts disclosed herein. In each of the drawings, identical reference numerals are used for like elements of the invention or elements of like function. For the sake of clarity, only those reference numerals are shown in the individual figures which are necessary for the description of the respective figure. For purposes of this description, the terms “upper,” “bottom,” “right,” “left,” “front,” “vertical,” “horizontal,” and derivatives thereof shall relate to the invention as oriented in FIG. 1.

As shown throughout the drawings, one embodiment of the electronics enclosure device 10 can include a main body 11, a removable cover 20 and a relocatable power tap 30 positioned therebetween.

As shown at FIG. 1, one embodiment of the main body 11 can include a generally rectangular shaped member having a top end 11a, a bottom end 11b, an open front end, a back surface 11d, and a pair of side surfaces 11e and 11f, that define a generally hollow interior space.

As will be described below, the main body 11 is intended to be mounted onto a wall or other structure so as to completely enclose one or more existing wall mounted electrical outlets and/or communication cable outlets, for example. Accordingly, in one embodiment the back wall 11d can include a generally flat surface onto which any number of user-supplied electronic components can be mounted and subsequently connected to the outlet.

Additionally, the back surface can include a plurality of mounting apertures 12, and at least one central opening 13. Each of the mounting apertures including a shape and size that is suitable for receiving mounting hardware such as a screw, for example, and the central opening 13 can include a shape and size that is greater than 3.5″×5.25″ which is the industry standard size for a single wall mounted outlet faceplate. Of course, any number of other shapes and sizes are also contemplated.

In one embodiment, a plurality of cable management apertures 14 can be positioned along the side walls of the main body for routing power and communication cables from the electronic components positioned within the device 10 to externally located devices such as a television, for example. Additionally, a plurality of air vents 15 can be positioned along the device body and can function to allow air to move through the device during operation.

In one embodiment, a plurality of slotted openings 17a or other such connectors can be provided along the main body for engagement by locking tabs 17b or complementary connectors that are located along the below described cover 40.

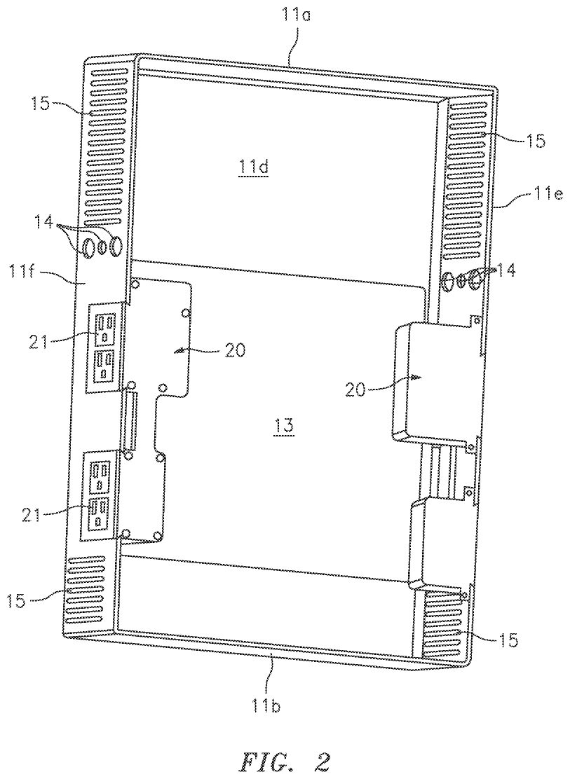

As shown best at FIG. 2, one embodiment of the device 10 can include one or more relocatable power taps 20, or other power distribution and/or surge protection components that can be secured within the main body. Each of the power taps can include one or more electrical outlets 21 which can be positioned within side openings 16 so as to be accessible by user devices not located within the device. In other embodiments, the power tap(s) can include internally located receptacles which can function to provide power and/or surge protection to any electrical components stored within the device.

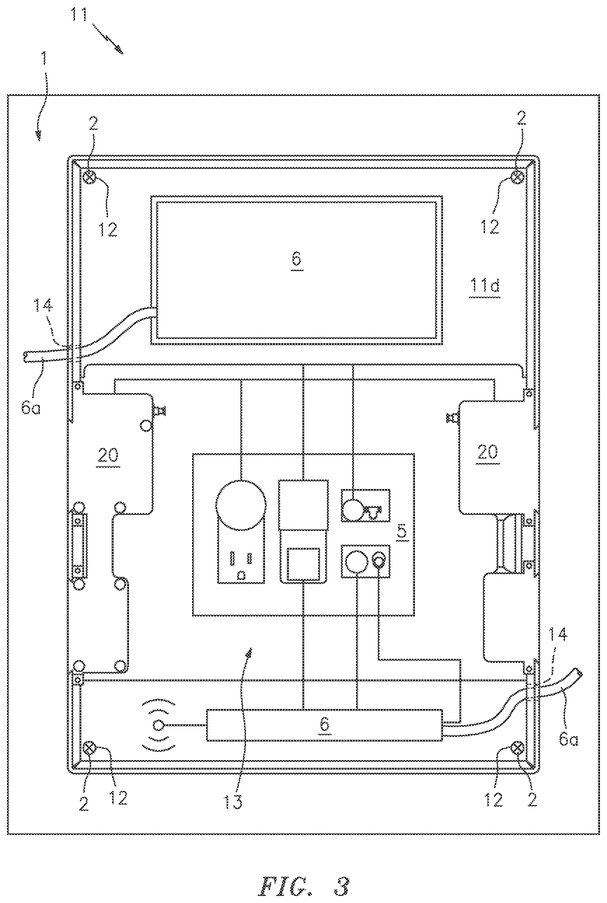

FIG. 3 illustrates one embodiment of the device 10 in operation. As shown, the main body 11 can be secured onto a wall 1 or other structure via hardware 2 such as screws that are positioned through the mounting apertures 12. The device can be positioned so that one or more outlets 5 such as the illustrated electrical, ethernet and cable outlets, for example, are located within the central opening 13 so as to be accessible.

When so positioned, any number of electronic components 6 such as the illustrated cable modem and internet router, for example, can be mounted onto the back surface 11d via connectors, such as double-sided tape or screws that can be secured through the back wall. In either instance, each of the components 6 can be plugged into a respective outlet 5, and cables 6a from the devices can be routed through the cable management apertures 14 to connect to externally located devices as needed.

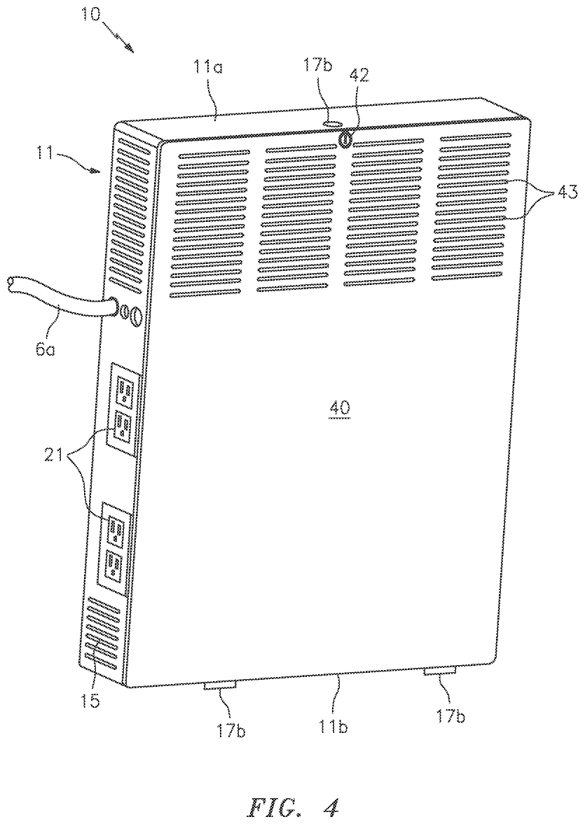

FIG. 4 illustrates one embodiment of the fully assembled electronics enclosure device 10. As shown, the cover 40 can also include a generally rectangular-shaped member having a shape and size that is complementary to the shape and size of the open front end of the main body 11.

In one embodiment, the cover can include a plurality of locking tabs 17b that are positioned so as to engage complementary shaped and located sleeves 17a along the main body 11. Additionally, the device 10 can also include a locking mechanism 42 such as the illustrated key operated cam lock, for example, that can lock the cover in place. Finally, the cover can also include a plurality of air vents 43.

Although described above as including generally rectangular-shaped elements, the inventive concepts are not limited to this shape, as any number of different shapes and sizes are contemplated. Moreover, any number of other types of connectors and locking mechanisms are contemplated and each such component can be positioned anywhere along the main body 11 and/or cover 40.

In the preferred embodiment, both the main body 11 and the cover 40 can be constructed from electrically non-conductive and fire-retardant plastic; however, any number of other materials that are relatively strong and stiff for their weight are also contemplated. Several nonlimiting examples include but are not limited to various metals or metal alloys (e.g., aluminum, steel, titanium, or alloys thereof), plastic/polymers (e.g., high-density polyethylene (HDPE), rigid polyvinyl chloride (PVC), or polyethylene terephthalate (PET)), and/or various composite materials (e.g., carbon fibers in a polymer matrix, fiberglass, etc.).

Accordingly, the above described electronics enclosure device advantageously provides access to electrical outlets while simultaneously safeguarding enclosed electrical components from unauthorized users.

As described herein, one or more elements of the electronics enclosure device 10 can be secured together utilizing any number of known attachment means such as, for example, screws, glue, compression fittings and welds, among others. Moreover, although the above embodiments have been described as including separate individual elements, the inventive concepts disclosed herein are not so limiting. To this end, one of skill in the art will recognize that one or more individually identified elements may be formed together as one or more continuous elements, either through manufacturing processes, such as welding, casting, or molding, or through the use of a singular piece of material milled or machined with the aforementioned components forming identifiable sections thereof.

As to a further description of the manner and use of the present invention, the same should be apparent from the above description. Accordingly, no further discussion relating to the manner of usage and operation will be provided.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Likewise, the terms “consisting” shall be used to describe only those components identified. In each instance where a device comprises certain elements, it will inherently consist of each of those identified elements as well.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. An electronics enclosure device, comprising:
a main body having a back wall and a plurality of side walls that define an interior space, said back wall including a flat surface for receiving a plurality of electronic components;
a central opening that is positioned along the back surface, said opening being configured to receive a wall mounted electrical outlet;
at least one air vent that is positioned along the main body; and
a cover that is removably secured to a front surface of the main body,
wherein the main body includes functionality for being mounted onto a wall.

2. The device of claim 1, further comprising:
at least one relocatable power tap that is positioned along the interior space of the main body.

3. The device of claim 2, wherein each of the at least one relocatable power tap includes functionality for engaging the wall mounted electrical outlet positioned within the central opening.

4. The device of claim 3, wherein each of the at least one relocatable power tap is configured to supply power to each of the plurality of electrical components positioned within the interior space.

5. The device of claim 3, wherein each of the at least one relocatable power tap includes at least one electrical outlet that is configured to supply power to a component that is not located within the interior space of the main body.

6. The device of claim 5, wherein each of the at least one electrical outlet is positioned within a side opening along the main body and includes a surface that is not enclosed within the interior space.

7. The device of claim 1, further comprising:
at least one cable management aperture that is positioned along the main body.

8. The device of claim 1, further comprising:
at least one air vent that is positioned along the cover.

9. The device of claim 1, wherein each of the main body and the cover are constructed from an electrically non-conductive material.

10. The device of claim 1, wherein each of the main body and the cover are constructed from a fire resistant and electrically non-conductive plastic material.
